(19) United States
(12) Patent Application Publication
(10) Pub. No.: US 2025/0390018 A1
(43) Pub. Date: Dec. 25, 2025

(54) PHOTOSENSITIVE RESIN COMPOSITION, PHOTOSENSITIVE ELEMENT, METHOD FOR FORMING RESIST PATTERN, AND METHOD FOR PRODUCING CIRCUIT BOARD

(71) Applicant: Resonac Corporation, Tokyo (JP)

(72) Inventors: Shiho TANAKA, Tokyo (JP); Naoki HIRAMATSU, Tokyo (JP); Keishi ONO, Tokyo (JP); Mao NARITA, Tokyo (JP)

(21) Appl. No.: 18/860,120

(22) PCT Filed: Mar. 4, 2024
(86) PCT No.: PCT/JP2024/008094

§ 371 Date: Oct. 25, 2024

(30) Foreign Application Priority Data
Mar. 17, 2023 (WO) PCT/JP2023/010672

(51) Int. Cl. G03F 7/004; G03F 7/031; G03F 7/033; H05K 3/18

(52) U.S. Cl. CPC G03F 7/0048; G03F 7/031; G03F 7/033; H05K 3/188; H05K 2203/0548

(57) ABSTRACT

A photosensitive resin composition contains a binder polymer, a photopolymerizable compound, a photopolymerization initiator, a dye, and a solvent, in which the solvent contains at least one selected from the group consisting of a ketone-based solvent having an alicyclic skeleton and an aromatic ether-based solvent.

### TECHNICAL FIELD

The present disclosure relates to a photosensitive resin composition, a photosensitive element, a method for forming a resist pattern, and a method for producing a circuit board.

### BACKGROUND ART

In the production of circuit boards, resist patterns are formed in order to obtain desired wirings. In the formation of resist patterns, a photosensitive resin composition has been widely used. The photosensitive resin composition can be prepared by dissolving components such as a binder polymer, a photopolymerizable compound, a photopolymerization initiator, and a dye, in a solvent such as toluene (see, for example, Patent Literature 1).

### CITATION LIST

### Patent Literature

Patent Literature 1: WO 2007/004619

### SUMMARY OF INVENTION

### Technical Problem

A photosensitive film formed using a conventional photosensitive resin composition shows a large change in sensitivity and color development after long-term storage, and there is a demand for improvement of sensitivity stability and color development stability. Therefore, an object of the present disclosure is to provide a photosensitive resin composition capable of forming a photosensitive film excellent in sensitivity stability and color development stability, and a photosensitive element, a method for forming a resist pattern, and a method for producing a circuit board, which use the photosensitive resin composition.

### Solution to Problem

The present disclosure provides a photosensitive resin composition, a photosensitive element, a method for forming a resist pattern, and a method for producing a circuit board described below.
[1] A photosensitive resin composition containing: a binder polymer; a photopolymerizable compound; a photopolymerization initiator; a dye; and a solvent, in which the solvent contains at least one selected from the group consisting of a ketone-based solvent having an alicyclic skeleton and an aromatic ether-based solvent.
[2] The photosensitive resin composition described in [1], in which the ketone-based solvent having an alicyclic skeleton contains at least one selected from the group consisting of cyclopentanone and cyclohexanone.
[3] The photosensitive resin composition described in [1], in which the aromatic ether-based solvent contains anisole.
[4] The photosensitive resin composition described in any one of [1] to [3], in which the solvent does not contain toluene.
[5] The photosensitive resin composition described in any one of [1] to [4], which is film-shaped.
[6] A photosensitive element including: a support; and a photosensitive layer formed using the photosensitive resin composition described in any one of [1] to [5] on the support.
[7] A method for forming a resist pattern, the method including: a step of forming a photosensitive layer using the photosensitive resin composition described in any one of [1] to [5] on a substrate; a step of photo-curing a part of the photosensitive layer; and a step of removing an uncured area of the photosensitive layer.
[8] A method for forming a resist pattern, the method including: a step of forming a photosensitive layer using the photosensitive element described in [6] on a substrate; a step of photo-curing a part of the photosensitive layer; and a step of removing an uncured area of the photosensitive layer.
[9] A method for producing a circuit board, the method including a step of subjecting a substrate on which a resist pattern is formed by the method for forming a resist pattern described in [7] to an etching or plating treatment to form a conductor pattern.
[10] A method for producing a circuit board, the method including a step of subjecting a substrate on which a resist pattern is formed by the method for forming a resist pattern described in [8] to an etching or plating treatment to form a conductor pattern.

### Advantageous Effects of Invention

According to the present disclosure, it is possible to provide a photosensitive resin composition capable of forming a photosensitive film excellent in sensitivity stability and color development stability, and a photosensitive element, a method for forming a resist pattern, and a method for producing a circuit board, which use the photosensitive resin composition. Furthermore, according to the present disclosure, since toluene, which is an environmentally regulated substance, may not be used as a solvent, it is possible to provide an environmentally friendly photosensitive resin composition, and a photosensitive element, a method for forming a resist pattern, and a method for producing a circuit board, which use the photosensitive resin composition.

### BRIEF DESCRIPTION OF DRAWINGS

FIG. 1 is a schematic cross-sectional view illustrating a photosensitive element according to an embodiment.

FIG. 2 is a schematic cross-sectional view illustrating a method for producing a circuit board according to an embodiment.

### DESCRIPTION OF EMBODIMENTS

Hereinafter, embodiments of the present disclosure will be described in detail.

In the present specification, the term “step” includes not only an independent step but also a step by which an intended action of the step is achieved, even though the step cannot be clearly distinguished from other steps. A numerical range that has been indicated by use of “to” indicates the range that includes the numerical values which are described before and after “to”, as the minimum value and the maximum value, respectively. The term “layer” includes a structure having a shape which is formed on a part, in addition to a structure having a shape which is formed on the whole surface, when the layer has been observed as a plan view. The term “(meth)acrylic acid” means at least one of “acrylic acid” and “methacrylic acid” corresponding thereto. The same applies to other analogous expressions such as (meth)acrylate.

In the present specification, the term “(poly)oxyethylene group” means an oxyethylene group or a polyoxyethylene group in which two or more ethylene groups are linked via an ether bond. The term “(poly)oxypropylene group” means an oxypropylene group or a polyoxypropylene group in which two or more propylene groups are linked via an ether bond. The term “EO-modified” compound means a compound having a (poly)oxyethylene group. The term “PO-modified” compound means a compound having a (poly)oxypropylene group. The term “EO/PO-modified” compound means a compound having a (poly)oxyethylene group and/or a (poly)oxypropylene group.

In the present specification, when a plurality of substances corresponding to each component exist in the composition, the amount of each component in the composition means the total amount of the plurality of substances that exist in the composition, unless otherwise specified. In the present specification, the term “solid content” refers to a non-volatile content of a photosensitive resin composition excluding volatile substances. That is, the term “solid content” refers to a component other than a solvent, remaining without volatile in drying of the photosensitive resin composition described below and also includes a component in a liquid, syrupy, or waxy state at room temperature (25° C.).

### Photosensitive Resin Composition

A photosensitive resin composition of the present embodiment contains a binder polymer (hereinafter, also referred to as “component (A)”), a photopolymerizable compound (hereinafter, also referred to as “component (B)”), a photopolymerization initiator (hereinafter, also referred to as “component (C)”), a dye (hereinafter, also referred to as “component (D)”), and a solvent (hereinafter, also referred to as “component (E)”). Here, the component (E) contains at least one selected from the group consisting of a ketone-based solvent having an alicyclic skeleton and an aromatic ether-based solvent. Hereinafter, respective components will be described.

### Component (A): Binder Polymer

The photosensitive resin composition contains one or two or more kinds of the components (A). Examples of the component (A) include an acrylic resin, a styrene-based resin, an epoxy-based resin, an amide-based resin, an amide-epoxy-based resin, an alkyd-based resin, and a phenol-based resin.

The component (A) may contain an acrylic resin from the viewpoint of alkali developability. The acrylic resin is a resin having a structural unit (monomer unit) derived from a (meth)acryloyl group-containing compound.

The (meth)acryloyl group-containing compound is a compound containing a (meth)acryloyl group. Examples of the (meth)acryloyl group-containing compound include hydroxyalkyl (meth)acrylate, (meth)acrylic acid, alkyl (meth)acrylate ester, aryl (meth)acrylate ester, cycloalkyl (meth)acrylate ester, acrylamides such as diacetone acrylamide, tetrahydrofurfuryl (meth)acrylate ester, dimethylaminoethyl (meth)acrylate ester, diethylaminoethyl (meth)acrylate ester, glycidyl (meth)acrylate ester, 2,2,2-trifluoroethyl (meth)acrylate, 2,2,3,3-tetrafluoropropyl (meth)acrylate, α-bromoacrylic acid, α-chloroacrylic acid, β-furyl (meth)acrylic acid, and β-styryl (meth)acrylic acid.

The acrylic resin may be, for example, a polymer (a) having at least one selected from the group consisting of a hydroxyalkyl (meth)acrylate unit, a (meth)acrylic acid unit, an alkyl (meth)acrylate ester unit, and an aryl (meth)acrylate ester unit.

The hydroxyalkyl (meth)acrylate unit is a structural unit derived from hydroxyalkyl (meth)acrylate. Examples of the hydroxyalkyl (meth)acrylate include hydroxymethyl (meth)acrylate, hydroxyethyl (meth)acrylate, hydroxypropyl (meth)acrylate, hydroxybutyl (meth)acrylate, hydroxypentyl (meth)acrylate, and hydroxyhexyl (meth)acrylate. In a case where the number of carbon atoms of the alkyl moiety in the hydroxyalkyl (meth)acrylate unit is 3 or more, the alkyl moiety may have a branched structure.

In a case where the polymer (a) has a hydroxyalkyl (meth)acrylate unit, the content of the hydroxyalkyl (meth)acrylate unit may be 0.5% by mass or more, 0.75% by mass or more, 1.0% by mass or more, 1.5% by mass or more, or 2.0% by mass or more from the viewpoint of dispersibility, and may be 20% by mass or less, 15% by mass or less, 8% by mass or less, 5% by mass or less, or 4% by mass or less from the viewpoint of water absorption properties, on the basis of the total amount of monomer units constituting the polymer (a).

The (meth)acrylic acid unit is a structural unit derived from a (meth)acrylic acid. In a case where the polymer (a) has a (meth)acrylic acid unit, the content of the (meth)acrylic acid unit may be 1% by mass or more, 5% by mass or more, 10% by mass or more, 15% by mass or more, 20% by mass or more, or 25% by mass or more, and may be 50% by mass or less, 45% by mass or less, 40% by mass or less, 35% by mass or less, or 30% by mass or less, on the basis of the total amount of monomer units constituting the polymer (a), from the viewpoint of resolution and adhesiveness.

The alkyl (meth)acrylate ester unit is a structural unit derived from an alkyl (meth)acrylate ester. The alkyl group of the alkyl (meth)acrylate ester may be, for example, a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, and may be an alkyl group having 1 to 4 carbon atoms from the viewpoint of release property.

In a case where the polymer (a) has an alkyl (meth)acrylate ester unit, the content of the alkyl (meth)acrylate ester unit may be 1% by mass or more, 2% by mass or more, or 3% by mass or more from the viewpoint of release property, and may be 80% by mass or less, 60% by mass or less, 50% by mass or less, 30% by mass or less, 20% by mass or less, 10% by mass or less, or 8% by mass or less from the viewpoint of resolution and adhesiveness, on the basis of the total amount of monomer units constituting the polymer (a).

The aryl (meth)acrylate ester unit is a structural unit derived from an aryl (meth)acrylate ester. Examples of the aryl (meth)acrylate ester include benzyl (meth)acrylate, phenyl (meth)acrylate, and naphthyl (meth)acrylate. In a case where the polymer (a) has an aryl (meth)acrylate ester unit, the content of the aryl (meth)acrylate ester unit may be 1% by mass or more, 5% by mass or more, 10% by mass or more, 15% by mass or more, or 18% by mass or more, and may be 50% by mass or less, 45% by mass or less, 40% by mass or less, 35% by mass or less, 30% by mass or less, 25% by mass or less, or 23% by mass or less, on the basis of the total amount of monomer units constituting the polymer (a), from the viewpoint of resolution and adhesiveness.

The polymer (a) may further have a structural unit derived from other monomer which is other than the (meth)acryloyl group-containing compound. The other monomer may be one or two or more kinds.

Examples of the other monomer include a styrene or a styrene derivative, acrylonitrile, ethers of vinyl alcohol such as vinyl-n-butyl ether, maleic acid, maleic anhydride, maleic acid monoesters such as monomethyl maleate, monoethyl maleate, and monoisopropyl maleate, fumaric acid, cinnamic acid, α-cyanocinnamic acid, itaconic acid, crotonic acid, and propiolic acid. Examples of the styrene derivative include vinyl toluene and α-methylstyrene.

In a case where the polymer (a) has a structural unit derived from styrene or a styrene derivative (hereinafter, also referred to as “styrene or styrene derivative unit”), the content of the styrene or styrene derivative unit may be 20% by mass or more, 30% by mass or more, 40% by mass or more, 45% by mass or more, 47% by mass or more, or 50% by mass or more from the viewpoint of resolution, and may be 90% by mass or less, 85% by mass or less, 80% by mass or less, 70% by mass or less, or 60% by mass or less from the viewpoint of developability, on the basis of the total amount of monomer units constituting the polymer (a).

The polymer (a) may be a polymer (a1) having a hydroxyalkyl (meth)acrylate unit, a (meth)acrylic acid unit, a styrene or styrene derivative unit, and an aryl (meth)acrylate ester unit, and may be a polymer (a2) having an alkyl (meth)acrylate ester unit, a (meth)acrylic acid unit, a styrene or styrene derivative unit, and an aryl (meth)acrylate ester unit.

The component (A) may contain a binder polymer other than the polymer (a), and may be composed of only the polymer (a). From the viewpoint of adhesiveness and resolution, the content of the polymer (a) in the component (A) may be 50 to 100% by mass and may be 80 to 100% by mass, on the basis of the total amount of the component (A).

The acid value of the polymer (a) may be 100 mgKOH/g or more, 120 mgKOH/g or more, 140 mgKOH/g or more, or 150 mgKOH/g or more from the viewpoint of developability, and may be 250 mgKOH/g or less, 240 mgKOH/g or less, or 230 mgKOH/g or less from the viewpoint of the adhesiveness (developing solution resistance) of a cured product of the photosensitive resin composition. The acid value of the polymer (a) can be adjusted by the content of the structural unit constituting the polymer (a) (for example, a (meth)acrylic acid unit). In a case where the component (A) contains other binder polymer which is other than the polymer (a), the acid value of the other binder polymer may also be within the above-described range.

The weight average molecular weight (Mw) of the polymer (a) may be 10000 or more, 15000 or more, 20000 or more, 25000 or more, 30000 or more, or 33000 or more from the viewpoint of the adhesiveness (developing solution resistance) of a cured product of the photosensitive resin composition, and may be 100000 or less, 80000 or less, 60000 or less, 50000 or less, or 40000 or less from the viewpoint of developability. The degree of dispersion (Mw/Mn) of the polymer (a) may be, for example, 1.0 or more or 1.5 or more, and may be 3.0 or less or 2.5 or less from the viewpoint of adhesiveness and resolution. In a case where the component (A) contains other binder polymer which is other than the polymer (a), the Mw of the other binder polymer may also be within the above-described range.

The weight average molecular weight and the degree of dispersion can be measured, for example, by gel permeation chromatography (GPC) using a calibration curve of standard polystyrene. More specifically, it is possible to measure under conditions described in Examples. Note that, as for a compound having a low molecular weight, in a case where measurement of the weight average molecular weight is difficult using the above-described method of measuring a weight average molecular weight, it is also possible to measure the molecular weights using other methods and to calculate an average thereof.

The content of the component (A) may be 20% by mass or more, 30% by mass or more, or 40% by mass or more from the viewpoint of film formability, and may be 90% by mass or less, 80% by mass or less, 70% by mass or less, or 65% by mass or less from the viewpoint of sensitivity and resolution, on the basis of the total amount of solid contents of the photosensitive resin composition.

The content of the component (A) may be 30 parts by mass or more, 35 parts by mass or more, or 40 parts by mass or more from the viewpoint of film formability, and may be 70 parts by mass or less, 65 parts by mass or less, or 60 parts by mass or less from the viewpoint of sensitivity and resolution, with respect to 100 parts by mass of the total amount of the component (A) and the component (B).

### Component (B): Photopolymerizable Compound

The photosensitive resin composition contains one or two or more kinds of the components (B). The component (B) may be a compound that is polymerized with light, and may be, for example, a compound having an ethylenically unsaturated bond. The component (B) may contain a polyfunctional monomer having two or more reactive groups reacting with radicals. The component (B) may contain a bisphenol A-type (meth)acrylate compound from the viewpoint of alkali developability, resolution, and release property after curing.

Examples of the bisphenol A-type (meth)acrylate compound include 2,2-bis(4-((meth)acryloxypolyethoxy)phenyl) propane, 2,2-bis(4-((meth)acryloxypolypropoxy) phenyl)propane, 2,2-bis(4-((meth)acryloxypolybutoxy)phenyl)propane, and 2,2-bis (4-((meth)acryloxypolyethoxypolypropoxy)phenyl)propane. The component (B) may contain 2,2-bis(4-((meth)acryloxypolyethoxy)phenyl)propane from the viewpoint of resolution and release property. Examples of the 2,2-bis(4-((meth)acryloxypolyethoxy)phenyl)propane include 2,2-bis(4-((meth)acryloxypentaethoxy)phenyl propane. As the 2,2-bis(4-((meth)acryloxypolyethoxy)phenyl)propane, a compound in which the number of oxyethylene groups is 10 or more may be used, a compound in which the number of oxyethylene groups is less than 10 may be used, and a compound in which the number of oxyethylene groups is 10 or more and a compound in which the number of oxyethylene groups is less than 10 may be used in combination.

In a case where the component (B) contains a bisphenol A-type (meth)acrylate compound, the content of the bisphenol A-type (meth)acrylate compound may be 20% by mass or more, 40% by mass or more, 60% by mass or more, 80% by mass or more, 85% by mass or more, or 90% by mass or more, and may be 100% by mass or less, or 95% by mass or less, on the basis of the total amount of the component (B), from the viewpoint of the resolution of a resist.

The component (B) may contain an α,β-unsaturated ester compound obtained by reacting polyhydric alcohol with α,β-unsaturated carboxylic acid from the viewpoint of resolution and flexibility. Examples of the α,β-unsaturated ester compound include polyethylene glycol di(meth)acrylate, polypropylene glycol di(meth)acrylate, polyalkylene glycol di(meth)acrylate such as EO-modified polypropylene glycol di(meth)acrylate, trimethylol propane di(meth)acrylate, trimethylol propane tri(meth)acrylate, EO-modified trimethylol propane tri(meth)acrylate, PO-modified trimethylol propane tri(meth)acrylate, EO/PO-modified trimethylol propane tri(meth)acrylate, tetramethylolmethane tri(meth)acrylate, and tetramethylolmethane tetra(meth)acrylate.

The component (B) may contain a compound having three or more (meth)acryloyl groups from the viewpoint of sensitivity and adhesiveness. Examples of such a compound include trimethylol propane tri(meth)acrylate, EO-modified trimethylol propane tri(meth)acrylate, PO-modified trimethylol propane tri(meth)acrylate, EO/PO-modified trimethylol propane tri(meth)acrylate, EO-modified pentaerythritol tetra(meth)acrylate, EO-modified ditrimethylol propane tetra(meth)acrylate, and EO-modified dipentaerythritol hexa(meth)acrylate.

In a case where the component (B) contains an α,β-unsaturated ester compound, the content of the α,β-unsaturated ester compound may be 1% by mass or more, 3% by mass or more, 5% by mass or more, or 8% by mass or more from the viewpoint of flexibility, and may be 20% by mass or less, 15% by mass or less, or 10% by mass or less from the viewpoint of resolution, on the basis of the total amount of the component (B).

The photosensitive resin composition may contain, as the component (B), other photopolymerizable compound which is other than the bisphenol A-type (meth)acrylate compound and the α,β-unsaturated ester compound.

Examples of the other photopolymerizable compound include nonylphenoxypolyethylene oxyacrylate, a phthalic acid-based compound, alkyl (meth)acrylate ester, and photopolymerizable compounds with at least one cationic polymerizable cyclic ether group in the molecule (such as an oxetane compound). From the viewpoint of resolution, adhesiveness, resist shape, and release property after curing, the other photopolymerizable compound may be at least one selected from the group consisting of nonylphenoxypolyethylene oxyacrylate and a phthalic acid-based compound.

Examples of the nonylphenoxypolyethylene oxyacrylate include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

Examples of the phthalic acid-based compound include γ-chloro-β-hydroxypropyl-β′-(meth)acryloyloxyethyl-o-phthalate (also known as: 3-chloro-2-hydroxypropyl-2-(meth)acryloyloxyethyl phthalate), β-hydroxyethyl-β′-(meth)acryloyloxyethyl-o-phthalate, and β-hydroxypropyl-β′-(meth)acryloyloxyethyl-o-phthalate.

In a case where the component (B) contains other photopolymerizable compounds, the content of the other photopolymerizable compounds may be 1% by mass or more, 3% by mass or more, or 5% by mass or more, and may be 30% by mass or less, 25% by mass or less, or 20% by mass or less, on the basis of the total amount of the component (B), from the viewpoint of resolution, adhesiveness, resist shape, and release property after curing. The component (B) may contain a compound having 2 to 40 of oxyethylene groups (EO groups) and/or oxypropylene groups (PO groups) in total in the molecule among the above-described compounds, from the viewpoint of adhesiveness and resolution. The total number of EO groups and/or PO groups may be 2 to 40 or 2 to 30 from the viewpoint of adhesiveness and resolution.

The component (B) may contain a compound having a urethane group. Examples of the compound having a urethane group include a compound having one to three urethane groups in the molecule, and a compound having four or more urethane groups in the molecule. The component (B) may not contain a compound having four or more urethane groups in the molecule.

Examples of the compound having a urethane group include a (meth)acrylate having a urethane group, and examples of the (meth)acrylate having a urethane group include EO-modified urethane di(meth)acrylate and EO,PO-modified urethane di(meth)acrylate. Examples of commercially available products of the EO-modified urethane di(meth)acrylate include “UA-11” and “UA-21EB” (manufactured by SHIN-NAKAMURA CHEMICAL Co., Ltd.). Examples of commercially available products of the EO,PO-modified urethane di(meth)acrylate include “UA-13” (manufactured by SHIN-NAKAMURA CHEMICAL Co., Ltd.).

In a case where the component (B) contains a compound having a urethane group, the content of the compound having a urethane group may be 5% by mass or more, 10% by mass or more, 20% by mass or more, 25% by mass or more, or 30% by mass or more, and may be 50% by mass or less, 45% by mass or less, 40% by mass or less, or 35% by mass or less, on the basis of the total amount of the component (B), from the viewpoint of improving the flexibility of the resist pattern.

The content of the component (B) may be 3% by mass or more, 10% by mass or more, or 25% by mass or more from the viewpoint of sensitivity and resolution, and may be 70% by mass or less, 60% by mass or less, or 50% by mass or less from the viewpoint of film formability, on the basis of the total amount of solid contents of the photosensitive resin composition.

### Component (C): Photopolymerization Initiator

The photosensitive resin composition contains one or two or more kinds of the components (C). Examples of the component (C) include a hexaarylbiimidazole compound; oxime ester compounds such as 1,2-octanedione-1-[4-(phenylthio)phenyl]-2-(o-benzoyloxime), 1-[9-ethyl-6-(2-methylbenzoyl)-9H-carbazol-3-yl]ethanone 1-(o-acetyloxime), and 1-phenyl-1,2-propanedione-2-[o-(ethoxycarbonyl)oxime]; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy) phenyl-2-(hydroxy-2-propyl)ketone, and 2-methyl-1-[4-(methylthio)phenyl]-2-morpholino-propanone-1; quinone such as alkylanthraquinone; benzoinether compounds such as benzoinalkyl ether; benzoin compounds such as benzoin and alkylbenzoin; benzyl derivatives such as benzyldimethylketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The component (C) may contain at least one selected from the group consisting of a hexaarylbiimidazole compound and an oxime ester compound, and may contain a hexaarylbiimidazole compound. The aryl group in the hexaarylbiimidazole compound may be a phenyl group or the like. A hydrogen atom bonded to the aryl group in the hexaarylbiimidazole compound may be substituted with a halogen atom (a chlorine atom or the like) or an alkoxy group (a methoxy group or the like).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer.

The content of the component (C) may be 0.1 parts by mass or more, 0.5 parts by mass or more, 1 part by mass or more, 3 parts by mass or more, 5 parts by mass or more, 6 parts by mass or more, 7 parts by mass or more, or 7.5 parts by mass or more, and may be 20 parts by mass or less, 15 parts by mass or less, 10 parts by mass or less, 9 parts by mass or less, or 8.5 parts by mass or less, with respect to 100 parts by mass of the total amount of the component (A) and the component (B), from the viewpoint of sensitivity and adhesiveness.

### Component (D): Dye

The photosensitive resin composition contains one or two or more kinds of the components (D). The component (D) is not particularly limited, and a known dye can be used. Examples of the component (D) include a leuco dye, phthalocyanine green, crystal violet, methyl orange, Nile Blue 2B, Victoria blue, malachite green, Basic Blue 20, diamond green, and spiron green. Examples of the leuco dye include leuco crystal violet and a fluoran dye.

From the viewpoint of sensitivity stability and color development stability, the component (D) may contain at least one selected from the group consisting of a leuco dye, malachite green, and spiron green. As the component (D), a leuco dye and malachite green may be used in combination, and a leuco dye and spiron green may be used in combination. In a case where the component (D) contains a leuco dye, the content of the leuco dye may be 0.01 parts by mass or more, 0.05 parts by mass or more, 0.10 parts by mass or more, 0.20 parts by mass or more, 0.30 parts by mass or more, 0.40 parts by mass or more, or 0.45 parts by mass or more, and may be 20 parts by mass or less, 10 parts by mass or less, 5 parts by mass or less, or 1 part by mass or less, with respect to 100 parts by mass of the total amount of the component (A) and the component (B).

The content of the component (D) may be 0.01 parts by mass or more, 0.05 parts by mass or more, 0.10 parts by mass or more, 0.20 parts by mass or more, 0.30 parts by mass or more, 0.40 parts by mass or more, or 0.50 parts by mass or more, and may be 20 parts by mass or less, 10 parts by mass or less, 5 parts by mass or less, or 1 part by mass or less, with respect to 100 parts by mass of the total amount of the component (A) and the component (B).

### Component (E): Solvent

The photosensitive resin composition contains one or two or more kinds of the components (E). The component (E) contains at least one selected from the group consisting of a ketone-based solvent having an alicyclic skeleton (hereinafter, also referred to as “component (E1)”) and an aromatic ether-based solvent (hereinafter, also referred to as “component (E2)”). By using, as the component (E), the component (E1) and the component (E2) described above, the photosensitive resin composition can form a photosensitive film excellent in sensitivity stability and color development stability.

The component (E1) and the component (E2) can achieve dissolubility equal to or more that of toluene, which has been conventionally used in the preparation of the photosensitive resin composition, and appropriate viscosity, and thus can be used as alternative solvents to toluene. Since the component (E) may not contain toluene, an environmentally friendly photosensitive resin composition can be obtained.

Examples of the component (E1) include cyclopentanone and cyclohexanone. Examples of the component (E2) include anisole. From the viewpoint of further excellent sensitivity stability and color development stability, the component (E) preferably contains at least one selected from the group consisting of cyclopentanone, cyclohexanone, and anisole, more preferably contains at least one selected from the group consisting of cyclopentanone and cyclohexanone, and further preferably contains cyclopentanone.

Since the component (E1) can improve the dissolubility of the component (for example, the component (C)) other than the component (E) contained in the photosensitive resin composition, the component (E1) may be used singly. By using the component (E1), the number of types of solvents can be reduced, which is advantageous in terms of environmental friendliness and workability.

The component (E) may contain other solvent to the extent that the effects of the present disclosure are not impaired. Examples of the other solvent include methanol and acetone.

The content of the component (E) may be 5 parts by mass or more, 8 parts by mass or more, 10 parts by mass or more, 15 parts by mass or more, 20 parts by mass or more, or 30 parts by mass or more, and may be 70 parts by mass or less, 60 parts by mass or less, 50 parts by mass or less, or 40 parts by mass or less, with respect to 100 parts by mass of the total amount of the component (A) and the component (B).

In a case where the component (E) contains the component (E1), the content of the component (El) may be 5 parts by mass or more, 8 parts by mass or more, 10 parts by mass or more, 15 parts by mass or more, 20 parts by mass or more, 25 parts by mass or more, 30 parts by mass or more, or 35 parts by mass or more, and may be 70 parts by mass or less, 60 parts by mass or less, 50 parts by mass or less, or 40 parts by mass or less, with respect to 100 parts by mass of the total amount of the component (A) and the component (B). In a case where the component (E) contains the component (E1), the content of the component (E1) may be 45% by mass or more, 50% by mass or more, 55% by mass or more, 60% by mass or more, 70% by mass or more, 80% by mass or more, 90% by mass or more, or 100% by mass, on the basis of the total amount of the component (E). In a case where the component (E) contains the component (E1), the content of the component (E1) may be 2.0 times or more, 2.5 times or more, 3.0 times or more, 3.5 times or more, 4.0 times or more, or 4.5 times or more the content of the component (C).

In a case where the component (E) contains the component (E2), the content of the component (E2) may be 5 parts by mass or more, 8 parts by mass or more, 10 parts by mass or more, 15 parts by mass or more, or 20 parts by mass or more, and may be 70 parts by mass or less, 60 parts by mass or less, 50 parts by mass or less, 40 parts by mass or less, or 30 parts by mass or less, with respect to 100 parts by mass of the total amount of the component (A) and the component (B). In a case where the component (E) contains the component (E2), the content of the component (E2) may be 40% by mass or more, 45% by mass or more, 50% by mass or more, or 55% by mass or more, and may be 70% by mass or less, or 60% by mass or less, on the basis of the total amount of the component (E). In a case where the component (E) contains the component (E2), the content of the component (E2) may be 2.0 times or more, 2.5 times or more, 3.0 times or more, 3.5 times or more, 4.0 times or more, or 4.5 times or more the content of the component (C).

### Component (F): Photosensitizer

The photosensitive resin composition may further contain a photosensitizer as a component (F). The component (F) is not particularly limited, and a known photosensitizer can be used. Examples of the component (F) include an anthracene-based sensitizer and a benzophenone compound. Examples of the anthracene-based sensitizer include 9,10-dibutoxyanthracene, 9,10-diphenylanthracene, and 9,10-diethoxyanthracene. From the viewpoint of adhesiveness and resolution, the anthracene-based sensitizer may be 9,10-dibutoxyanthracene. Examples of the benzophenone compound include benzophenone, methylbenzophenone, 4,4′-dichlorobenzophenone, 4,4′-bis(diethylamino)benzophenone, Michler's ketone, and 4-benzoyl-4′-methyldiphenyl sulfide.

In the photosensitive resin composition contains the component (F), the content of the component (F) may be 0.01 parts by mass or more, 0.02 parts by mass or more, 0.2 parts by mass or more, 0.3 parts by mass or more, 0.4 parts by mass or more, or 0.5 parts by mass or more from the viewpoint of sensitivity, adhesiveness, and resolution, and may be 1.5 parts by mass or less, 1.0 part by mass or less, 0.8 parts by mass or less, 0.75 parts by mass or less, or 0.7 parts by mass or less from the viewpoint of resist pattern shape, with respect to 100 parts by mass of the total amount of the component (A) and the component (B).

### Component (G): Polymerization Inhibitor

The photosensitive resin composition may further contain a polymerization inhibitor as a component (G). Examples of the polymerization inhibitor include t-butylcatechol and 4-hydroxy-2,2,6,6-tetramethylpiperidine-N-oxyl.

In a case where the photosensitive resin composition contains the component (G), the content of the component (G) may be 0.001 parts by mass or more, 0.005 parts by mass or more, 0.008 parts by mass or more, 0.01 or 0.015 parts by mass or more from the viewpoint of sensitivity and resolution, and may be 0.1 parts by mass or less, 0.05 parts by mass or less, or 0.03 parts by mass or less from the viewpoint of sensitivity and adhesiveness, with respect to 100 parts by mass of the total amount of the component (A) and the component (B).

The photosensitive resin composition may further contain one or two or more kinds of other components which are other than the above-described components. Examples of the other components include a hydrogen donor (such as bis[4-(dimethylamino)phenyl]methane, bis [4-(diethylamino)phenyl]methane, and N-phenylglycine), tribromophenylsulfone, a thermal coloring inhibitor, a plasticizer (such as p-toluenesulfonamide), a pigment, a filler, an antifoaming agent, a flame retardant, a stabilizer, an adhesiveness imparting agent, a leveling agent, a release promoter, an antioxidant, an aroma, an imaging agent, and a thermal crosslinking agent. The content of the other components may be 0.005 parts by mass or more or 0.01 parts by mass or more, and may be 20 parts by mass or less, with respect to 100 parts by mass of the total amount of the component (A) and the component (B).

The photosensitive resin composition may be in a liquid form and may be film-shaped (photosensitive film). The photosensitive resin composition can be used, for example, as a negative photosensitive resin composition. The photosensitive resin composition can be suitably used in a method for forming a resist pattern and a method for producing a circuit board described below.

### Photosensitive Element

A photosensitive element of the present embodiment includes a support and a photosensitive layer formed using the above-described photosensitive resin composition on the support. The photosensitive element may further include a protective layer on the photosensitive layer.

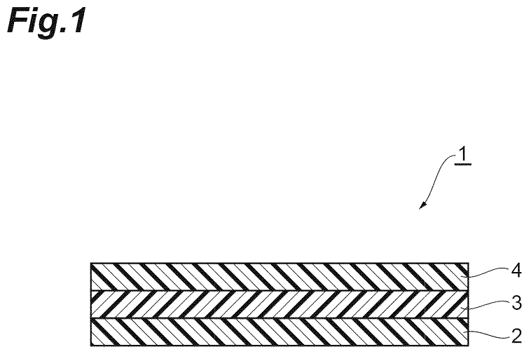

FIG. 1 is a schematic cross-sectional view illustrating a photosensitive element according to an embodiment. As illustrated in FIG. 1, a photosensitive element 1 includes a support 2, a photosensitive layer 3 provided on the support 2, and a protective layer 4 provided on the photosensitive layer 3 on a side opposite to the support 2.

Examples of constituent materials for the support include polyesters such as polyethylene terephthalate (PET), polybutylene terephthalate (PBT), and polyethylene-2,6-naphthalate (PEN); and polyolefins such as polypropylene and polyethylene. The support may have a polyester film and may have a PET film from the viewpoint of easily suppressing occurrence of defects of a resist.

The haze of the support may be 0.01 to 5.0%, 0.01 to 1.5%, 0.01 to 1.0%, or 0.01 to 0.5%. The haze can be measured using a commercially available haze meter (turbidimeter) according to the method defined in JIS K 7105. The haze can be measured, for example, using a commercially available turbidimeter such as NDH-5000 (manufactured by NIPPON DENSHOKU INDUSTRIES CO., LTD., trade name).

The support is a light transmissive film and may be a transparent resin film. The support may be a highly transparent resin film having a light transmission (for example, light transmission in the whole range of wavelengths of 380 to 780 nm) of 80% or more. The light transmission of the support may be 85% or more or 90% or more. Examples of the highly transparent resin film include a highly transparent PET film. The light transmission can be measured using a commercially available haze meter (for example, trade name “NDH-5000” manufactured by NIPPON DENSHOKU INDUSTRIES CO., LTD.).

The thickness of the support may be 1 μm or more, 5 μm or more, or 10 μm or more, from the viewpoint of easily suppressing the damage of the support when the support is peeled off from the photosensitive layer. The thickness of the support may be 100 μm or less, 50 μm or less, 30 μm or less, or 20 μm or less, from the viewpoint of easily and suitably performing exposure in the case of exposure through the support.

The protective layer may be a polymer film having heat resistance and solvent resistance, and for example, a polyolefin film such as a polyethylene film or a polypropylene film can be used. In particular, by using a polyethylene film as a protective layer, the winding misalignment of the photosensitive element can be suppressed, and static electricity is less likely to be generated when the protective layer is released from the photosensitive layer, so that the damage of the photosensitive layer can be suppressed.

The thickness of the protective layer may be 1 μm or more, 5 μm or more, 10 μm or more, or 15 μm or more, from the viewpoint of easily suppressing the damage of the protective layer when the photosensitive layer and the support are laminated on the substrate while the protective layer is peeled off. From the viewpoint of easily improving productivity, the thickness may be 100 μm or less, 50 μm or less, 40 μm or less, or 30 μm or less.

The photosensitive layer may be the above-described photosensitive film. The photosensitive layer can be formed, for example, by heating and drying the photosensitive resin composition. When the photosensitive resin composition is heated and the dried, the component (E) is volatilized and removed, but cannot be completely removed. The component (E) remains in the photosensitive layer. When the photosensitive layer contains the component (E), the sensitivity stability and the color development stability are excellent.

The content of the component (E) in the photosensitive layer may be 1 ppm by mass or more, 5 ppm by mass or more, 25 ppm by mass or more, 50 ppm by mass or more, 80 ppm by mass or more, 90 ppm by mass or more, 100 ppm by mass or more, 110 ppm by mass or more, 120 ppm by mass or more, or 130 ppm by mass or more from the viewpoint of sensitivity stability and color development stability, and may be 6000 ppm by mass or less, 5500 ppm by mass or less, 5000 ppm by mass or less, 4500 ppm by mass or less, 4000 ppm by mass or less, 3500 ppm by mass or less, 3000 ppm by mass or less, 2500 ppm by mass or less, 2000 ppm by mass or less, 1500 ppm by mass or less, 1000 ppm by mass or less, 500 ppm by mass or less, 250 ppm by mass or less, or 150 ppm by mass or less from the viewpoint of resistance to edge fusion. Furthermore, the content of the component (E) in the photosensitive layer may be 80 ppm by mass or more, 90 ppm by mass or more, 100 ppm by mass or more, 110 ppm by mass or more, 120 ppm by mass or more, or 130 ppm by mass or more, from the viewpoint of followability. The content of the component (E) in the photosensitive layer can be adjusted by the drying temperature and the drying time when the photosensitive resin composition is heated and dried.

The post-drying thickness of the photosensitive layer (after a solvent is volatilized) may be 1 μm or more, 5 μm or more, 10 μm or more, or 15 μm or more from the viewpoint of facilitating coating and improving productivity, and may be 100 μm or less, 50 μm or less, 40 μm or less, or 30 μm or less from the viewpoint of adhesiveness and resolution. A preferred range of the content of the component (E) in the photosensitive layer may vary depending on the thickness of the photosensitive layer. For example, in a case where the thickness of the photosensitive layer is 25 μm, the content of the component (E) in the photosensitive layer may be 115 ppm by mass or more, 120 ppm by mass or more, 125 ppm by mass or more, 130 ppm by mass or more, 135 ppm by mass or more, or 140 ppm by mass or more, from the viewpoint of sensitivity stability and color development stability. In a case where the thickness of the photosensitive layer is 35 μm, the content of the component (E) in the photosensitive layer may be 180 ppm by mass or more, 200 ppm by mass or more, 250 ppm by mass or more, 300 ppm by mass or more, or 320 ppm by mass or more, from the viewpoint of sensitivity stability and color development stability.

The photosensitive element 1 can be obtained, for example, as follows. First, the photosensitive layer 3 is formed on the support 2. The photosensitive layer 3 can be formed, for example, by applying a photosensitive resin composition to form a coating layer and drying this coating layer. Next, the protective layer 4 is formed on a surface of the photosensitive layer 3 on a side opposite to the support 2.

The coating layer is formed, for example, by known methods such as roll coating, comma coating, gravure coating, air knife coating, die coating, and bar coating. The drying of the coating layer is performed, for example, at 70 to 150° C. for about 5 to 30 minutes.

In another embodiment, the photosensitive element may further include other layers such as a cushion layer, an adhesive layer, a light-absorbing layer, and a gas barrier layer.

The photosensitive element 1 may be, for example, in a sheet form, and may be in the form of a photosensitive element roll wound around a core into a roll. In the photosensitive element roll, the photosensitive element 1 is preferably wound such that the support 2 comes on the outer side. The core is formed, for example, with polyethylene, polypropylene, polystyrene, polyvinyl chloride, an acrylonitrile-butadiene-styrene copolymer, or the like. At end faces of the photosensitive element roll, end-face separators may be provided from the viewpoint of protecting the end faces, and moisture-proof end-face separators may be provided from the viewpoint of resistance to edge fusion. The photosensitive element 1 may be wrapped, for example, with a black sheet having low moisture permeability.

The photosensitive element of the present embodiment can be suitably used in a method for forming a resist pattern and a method for producing a circuit board described below.

### Method for Forming Resist Pattern

A method for forming a resist pattern of the present embodiment includes a step (hereinafter, also referred to as “photosensitive layer formation step”) of forming a photosensitive layer using the above-described photosensitive resin composition or the above-described photosensitive element on a substrate, a step (hereinafter, also referred to as “exposure step”) of photo-curing a part of the photosensitive layer, and a step (hereinafter, also referred to as “development step”) of removing an uncured area of the photosensitive layer, and may further include other steps as necessary. Note that, the resist pattern can be said to be a photo-cured product pattern or a relief pattern of the photosensitive resin composition.

### Photosensitive Layer Formation Step

In the photosensitive layer formation step, a photosensitive layer is formed using the photosensitive resin composition or the photosensitive element on a substrate. The above-described substrate is not particularly limited, and a substrate for circuit formation including an insulation layer and a conductor layer formed on the insulation layer, a die pad (a base material for lead frame) such as an alloy base material, or the like is generally used.

As a method for forming a photosensitive layer on a substrate, a photosensitive layer can be formed on a substrate, for example, by removing the protective layer from the photosensitive element and pressure-bonding the photosensitive layer of the photosensitive element to the substrate while heating the photosensitive layer. Thereby, a laminate including the substrate, the photosensitive layer, and the support in this order is obtained.

The photosensitive layer formation step may be performed under reduced pressure from the viewpoint of adhesiveness and followability. The heating during pressure-bonding may be performed at a temperature of 70 to 130° C., and the pressure-bonding may be performed at a pressure of 0.1 to 1.0 MPa (1 to 10 kgf/cm²), but these conditions can be appropriately selected as necessary. Note that, when the photosensitive layer of the photosensitive element is heated to 70 to 130° C., there is no need to preheat the substrate in advance, but the substrate can also be preheated in order to further improve the adhesiveness and the followability.

### Exposure Step

In the exposure step, the photosensitive layer may be exposed by an active light ray through the support, and the photosensitive layer may be exposed by an active light ray after the support is peeled off. Thereby, the exposed area irradiated with an active light ray is photo-cured to form a photo-cured area (latent image).

As the exposure method, a known exposure method can be applied, and examples thereof include a method of emitting active light rays imagewise through a negative or positive mask pattern, referred to as artwork (mask exposure method), an LDI (Laser Direct Imaging) exposure method, and a method of emitting active light rays projecting an image of a photomask imagewise through a lens (projection exposure method). Among these, from the viewpoint of resolution, an LDI exposure method or a projection exposure method may be used. The projection exposure method can also be described as an exposure method using an active light ray with an attenuated energy dose.

The light source for the active light ray is not particularly limited as long as it is a known light source to be generally used, and for example, a carbon arc lamp, a mercury vapor arc lamp, an ultrahigh pressure mercury lamp, a high-pressure mercury lamp, a xenon lamp, a gas laser such as an argon laser, a solid-state laser such as a YAG laser, and those efficiently emitting ultraviolet rays such as a semiconductor laser including a gallium nitride blue-violet laser or the like, are used.

Among these, from the viewpoint of improving resolution and alignment in a well-balanced manner, a light source capable of emitting i-line monochromatic light with an exposure wavelength of 365 nm, a light source capable of emitting h-line monochromatic light with an exposure wavelength of 405 nm, or a light source capable of emitting active light ray with an exposure wavelength of ihg mixed lines, and a light source capable of emitting i-line monochromatic light with an exposure wavelength of 365 nm or an h-line monochromatic light with an exposure wavelength of 405 nm may be used. Examples of the light source capable of emitting i-line monochromatic light with an exposure wavelength of 365 nm include an ultrahigh pressure mercury lamp. Examples of the light source capable of emitting h-line monochromatic light with an exposure wavelength of 405 nm include a blue-violet laser diode with a wavelength of 405 nm.

In the method for forming a resist pattern of the present embodiment, from the viewpoint of adhesiveness, post exposure bake

(PEB) may be performed after the exposure step and before development step. The temperature in the case of performing PEB may be 50 to 100° C. The heating may be performed using a heating machine such as a hot plate, a box-type dryer, or a heating roll.

### Development Step

In the development step, an uncured area of the photosensitive layer is removed from the substrate. In a case where the photosensitive layer is exposed through the support, the support and the uncured area of the photosensitive layer are removed from the substrate. By the development step, a resist pattern composed of the photo-cured area obtained by photo-curing the above-described photosensitive layer is formed on the substrate. The development method may be wet development or dry development, and the wet development is preferred.

In the case of the wet development, development can be performed by a known wet development method using a developing solution corresponding to the photosensitive resin composition. Examples of the wet development method include methods using dipping, paddling, high-pressure spraying, brushing, scrubbing, shaking immersion, and the like. These wet development methods may be used singly or two or more kinds of these methods for development.

The developing solution is appropriately selected in accordance with the configuration of the photosensitive resin composition, and may be, for example, an alkaline developing solution or an organic solvent developing solution.

From the viewpoint of being safe and stable and having good handleability, an alkaline developing solution may be used as the developing solution. The alkaline developing solution may be aqueous solutions containing bases such as alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphate such as sodium pyrophosphate and potassium pyrophosphate; borax; sodium metasilicate; tetramethylammonium hydroxide; ethanolamine; ethylenediamine; diethylenetriamine; 2-amino-2-hydroxymethyl-1,3-propanediol; 1,3-diamino-2-propanol; and morpholine.

From the viewpoint of environmental friendliness, an inorganic alkaline developing solution may be used. As the inorganic alkaline developing solution, for example, a 0.1 to 5% by mass dilute solution of sodium carbonate, a 0.1 to 5% by mass dilute solution of potassium carbonate, a 0.1 to 5% by mass dilute solution of sodium hydroxide, or a 0.1 to 5% by mass dilute solution of sodium tetraborate can be used.

The pH of the alkaline developing solution to be used for development may be set in a range of 9 to 11, and the temperature of the alkaline developing solution can be adjusted according to the developability of the photosensitive layer. Into the alkaline developing solution, for example, a surfactant, an antifoaming agent, a small amount of an organic solvent for promoting development, or the like may be incorporated. Examples of the organic solvent used for the alkaline developing solution include 3-acetone alcohol, acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent used for the organic solvent developing solution include 1,1,1-trichloroethane, N-methyl-2-pyrrolidone, N,N-dimethylformamide, cyclohexanone, methyl isobutyl ketone, and γ-butyrolactone. From the viewpoint of anti-flammability, it may be possible that water is added to these organic solvents within a range of 1 to 20% by mass to prepare the organic solvent developing solution.

### Other Steps

The method for forming a resist pattern of the present embodiment may include, after removing the uncured area in the development step, a step of further curing the resist pattern by performing heating at 60 to 250° C. or exposure at an exposure dose of 0.2 to 10 J/cm², as necessary.

### Method for Producing Circuit Board

A method for producing a circuit board of the present embodiment includes a step of subjecting a substrate having a resist pattern formed by the above-described method for forming a resist pattern to an etching treatment or a plating treatment to form a conductor pattern (wiring layer), and may include other step such as a resist pattern removing step, as necessary.

In the etching treatment, a conductor pattern is formed by using, as a mask, a resist pattern formed on the substrate including the conductor layer, and etching away the conductor layer of the substrate not covered with a resist.

The etching treatment method is appropriately selected depending on the conductor layer to be removed. Examples of an etching solution include a cupric chloride solution, a ferric chloride solution, an alkali etching solution, and a hydrogen peroxide-based etching solution. From the viewpoint of its favorable etch factor, a ferric chloride solution may be used as the etching solution.

In the plating treatment, copper, solder, or the like is plated on the conductor layer of the substrate not covered with a resist by using, as a mask, a resist pattern formed on the substrate including the conductor layer. After the plating treatment, a conductor pattern is formed by removing the resist by the removal of the resist pattern described below and further etching the conductor layer covered by the resist.

The plating treatment method may be an electrolytic plating treatment and may be an electroless plating treatment, and examples thereof include copper plating such as copper sulfate plating or copper pyrophosphate plating, solder plating such as high throw solder plating, nickel plating such as Watts bath (nickel sulfate-nickel chloride) plating and nickel sulfamate plating, and gold plating such as hard gold plating and soft gold plating.

After the etching treatment or the plating treatment, the resist pattern on the substrate is removed. The resist pattern can be removed by being peeled off, for example, with an aqueous solution of stronger alkalinity than the alkaline developing solution used in the development step. As this strong alkaline aqueous solution, for example, a 1 to 10% by mass sodium hydroxide aqueous solution, a 1 to 10% by mass potassium hydroxide aqueous solution, and the like are used. Of these, a 1 to 5% by mass sodium hydroxide aqueous solution or potassium hydroxide aqueous solution may be used.

Examples of the method for removing a resist pattern include a dip method and a spray method, and these may be used singly or in combination.

In a case where the resist pattern is removed after the plating treatment, a desired circuit board can be produced by further subjecting the conductor layer covered by the resist to the etching treatment to form a conductor pattern. The etching treatment method at this time is appropriately selected depending on the conductor layer to be removed. For example, the above-described etching solution can be applied.

The method for producing a circuit board of the present embodiment can be applied not only to production of single-layer circuit boards but also to production of multilayered circuit boards, and can also be applied to production of circuit boards having small diameter through-holes, and the like.

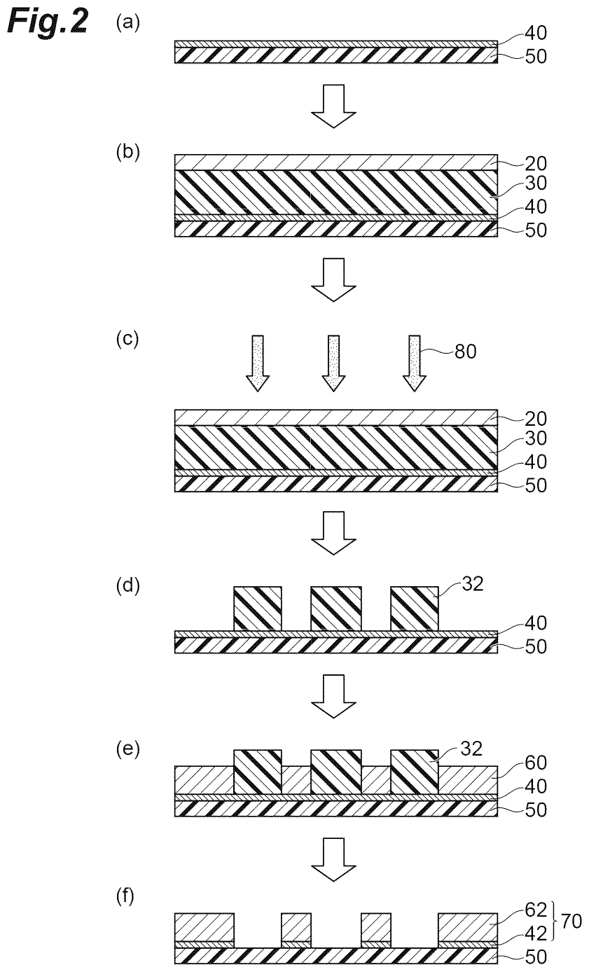

The method for producing a circuit board of the present embodiment can be suitably used for producing a high density package substrate, particularly, for producing a circuit board by a semi-additive process. Note that, an example of a step of producing a circuit board by a semi-additive process is illustrated in FIG. 2.

In (a) in FIG. 2, a substrate (substrate for circuit formation) having a conductor layer 40 formed on an insulation layer 50 is prepared. The conductor layer 40 is, for example, a copper layer. In (b) in FIG. 2, by the above-described photosensitive layer formation step, a photosensitive layer 30 and a support 20 are formed on the conductor layer 40 of the substrate. In (c) in FIG. 2, by the above-described exposure step, the photosensitive layer 30 is irradiated with an active light ray 80 projecting an image of a photomask image through the support 20 to form a photo-cured area on the photosensitive layer 30. In (d) in FIG. 2, by the development step, an area other than the photo-cured area formed by the above-described exposure step is removed from the substrate to form a resist pattern 32, which is the photo-cured area, on the substrate.

In (e) in FIG. 2, a plated layer 60 is formed on the conductor layer 40 of the substrate not covered with resist, by a plating treatment using the resist pattern 32, which is the photo-cured area, as a mask. The materials for the conductor layer 40 and the plated layer 60 may be the same as or different from each other. In a case where the materials for the conductor layer 40 and the plated layer 60 are the same, the conductor layer 40 and the plated layer 60 may be integrated.

In (f) in FIG. 2, the resist pattern 32, which is the photo-cured area, is released and removed with a strong alkaline aqueous solution. The strong alkaline developing solution may be, for example, a 1 to 10% by mass sodium hydroxide aqueous solution, a 1 to 10% by mass potassium hydroxide aqueous solution, and the like. Next, the conductor layer 40 masked by the resist pattern 32 is removed by a flash etching treatment to form a conductor pattern 70 including a plated layer 62 after the etching treatment and a conductor layer 42 after the etching treatment. An etching solution is appropriately selected in accordance with the type of the conductor layer 40, and may be, for example, a cupric chloride solution, a ferric chloride solution, an alkali etching solution, a hydrogen peroxide etching solution, and the like. Note that, although the projection exposure method has been described in FIG. 2, the resist pattern 32 may be formed by using a mask exposure method or an LDI exposure method in combination therewith. By using the photosensitive element of the present embodiment, a circuit board having a fine conductor pattern can be produced.

Hereinbefore, preferred embodiments of the present disclosure have been described; however, the present disclosure is not limited to the above-described embodiments by any means.

### EXAMPLES

Hereinafter, the present disclosure will be further specifically described by means of Examples; however, the present disclosure is not limited to these Examples.

### Synthesis of Component (A)

A solution (a) was prepared by mixing 27 parts by mass of methacrylic acid, 50 parts by mass of styrene, 3 parts by mass of 2-hydroxyethyl methacrylate, and 20 parts by mass of benzyl methacrylate with 0.9 parts by mass of azobisisobutyronitrile. A solution (b) was prepared by dissolving 0.5 parts by mass of azobisisobutyronitrile in 50 parts by mass of a mixed liquid (x) of 30 parts by mass of propylene glycol monomethyl ether and 20 parts by mass of toluene. After charging 500 g of the mixed liquid (x) in a flask equipped with a stirrer, a reflux condenser, a thermometer, a dropping funnel, and a nitrogen gas inlet tube, stirring was performed while blowing nitrogen gas into the flask, and the temperature was raised to 80° C. The above-described solution (a) was added dropwise to the above-described mixed liquid in the flask over 4 hours at a constant dropwise addition rate, and then stirring was performed at 80° C. for 2 hours. Next, the above-described solution (b) was added dropwise to the solution in the flask over 10 minutes at a constant dropwise addition rate, and then the solution in the flask was stirred at 80° C. for 3 hours. Further, the solution in the flask was heated to 90° C. over 30 minutes and kept at 90° C. for 2 hours, stirring was then stopped, and the solution was cooled to room temperature (25° C.), thereby obtaining a solution of a binder polymer A1. The non-volatile content (solid content) of the solution of the binder polymer A1 was 49.8% by mass. The weight average molecular weight of the binder polymer A1 was 35000.

A solution (a) was prepared by mixing 27 parts by mass of methacrylic acid, 45 parts by mass of styrene, 5 parts by mass of methyl methacrylate, and 23 parts by mass of benzyl methacrylate with 0.9 parts by mass of azobisisobutyronitrile. A solution (b) was prepared by dissolving 0.5 parts by mass of azobisisobutyronitrile in 50 parts by mass of a mixed liquid (x) of 30 parts by mass of propylene glycol monomethyl ether and 20 parts by mass of acetone. After charging 500 g of the mixed liquid (x) in a flask equipped with a stirrer, a reflux condenser, a thermometer, a dropping funnel, and a nitrogen gas inlet tube, stirring was performed while blowing nitrogen gas into the flask, and the temperature was raised to 80° C. The above-described solution (a) was added dropwise to the above-described mixed liquid in the flask over 4 hours at a constant dropwise addition rate, and then stirring was performed at 80° C. for 2 hours. Next, the above-described solution (b) was added dropwise to the solution in the flask over 10 minutes at a constant dropwise addition rate, and then the solution in the flask was stirred at 80° C. for 3 hours. Further, the solution in the flask was heated to 90° C. over 30 minutes and kept at 90° C. for 2 hours, stirring was then stopped, and the solution was cooled to room temperature, thereby obtaining a solution of a binder polymer A2. The non-volatile content (solid content) of the solution of the binder polymer A2 was 49.8% by mass. The weight average molecular weight of the binder polymer A2 was 47000.

Note that, the weight average molecular weight was measured by gel permeation chromatography (GPC) and was derived by conversion using a calibration curve of standard polystyrene. Conditions for GPC are as described below.

### (GPC Conditions)

Pump: Hitachi L-6000 type (manufactured by Hitachi, Ltd., trade name)
Column: Three columns below in total
   Gelpack GL-R420
   Gelpack GL-R430
   Gelpack GL-R440 (above all, manufactured by Resonac Corporation, trade name)
Eluent: Tetrahydrofuran
Measurement temperature: 40° C.
Flow rate: 2.05 mL/min
Detector: Hitachi L-3300 type RI (manufactured by Hitachi,

Ltd., trade name)

### Preparation of Photosensitive Resin Composition

Respective components shown in Table 1 were mixed at a blending amount (parts by mass) shown in Table 1 to prepare each of photosensitive resin compositions. Note that, the blending amount (parts by mass) of a component other than the solvent shown in Table 1 is the mass of non-volatile content (solid content amount). The details of respective components shown in Table 1 are as follows.

### Binder Polymer

A1: Binder polymer A1 synthesized above
A2: Binder polymer A2 synthesized above

### (Photopolymerizable Compound)

FA-321M (70): Propylene glycol monomethyl ether 70% solution of 2,2-bis(4-(methacryloxyethoxy)phenyl)propane (an adduct of an average of 10 mol of ethylene oxide) (manufactured by Resonac Corporation).
FA-024M: (PO) (EO) (PO)-modified dimethacrylate (manufactured by Resonac Corporation, an adduct of an average of 6 mol of ethylene oxide and an average of 12 mol of propylene oxide (total value)) BP-2EM: 2,2-Bis(4-(methacryloxypolyethoxy)phenyl)propane (manufactured by Kyoeisha Chemical Co., Ltd., EO group: 5.2 (total value)).
UA-11: EO-modified urethane di(meth)acrylate (manufactured by SHIN-NAKAMURA CHEMICAL Co., Ltd.)
UA-13: EO,PO-modified urethane di(meth)acrylate (manufactured by SHIN-NAKAMURA CHEMICAL Co., Ltd.)

### (Photopolymerization Initiator)

B-CIM: 2,2′-Bis(o-chlorophenyl)-4,4′,5,5′-tetraphenyl-1,2′-biimidazole (manufactured by Hampford Research Inc.)

### (Photosensitizer)

DBA: 9,10-Dibutoxyanthracene (manufactured by Kawasaki Kasei Chemicals Ltd.)
EAB: 4,4′-Bis (diethylamino)benzophenone (manufactured by Hodogaya Chemical Co., Ltd.)

### (Polymerization Inhibitor)

TBC: 4-t-Butylcatechol (manufactured by DIC Corporation, trade name “Q-TBC-5P”)

### (Dye)

LCV: Leuco crystal violet (manufactured by Yamada Chemical Co., Ltd.)
MKG: Malachite green (manufactured by OSAKA ORGANIC CHEMICAL INDUSTRY LTD.)

### Production of Photosensitive Element

A polyethylene terephthalate film (manufactured by TEIJIN LIMITED, trade name “HTF-01”) having a thickness of 16 μm was prepared as the support, and the photosensitive resin composition was applied onto the support to have a uniform thickness and subsequently dried with a hot air convection drier set at 70° C. and 110° C., thereby forming a photosensitive layer having a post-drying thickness of 25 μm or 35 μm. A polyethylene film (manufactured by TAMAPOLY CO., LTD., trade name “NF-15”) as the protective layer was attached onto this photosensitive layer, thereby obtaining a photosensitive element including the support, the photosensitive layer, and the protective layer laminated in this order.

### Evaluation

### Cyclopentanone Residual Amount

The photosensitive layer in the photosensitive element was introduced into Headspace Sampler HS-20 manufactured by SHIMADZU CORPORATION and heated at 150° C. for 15 minutes, and then the amount of cyclopentanone contained in the photosensitive layer was measured under the following measurement conditions by using GCMS QP-2020NX manufactured by SHIMADZU CORPORATION. As a result of the measurement, the amounts of cyclopentanone in the photosensitive layer obtained using the photosensitive resin compositions of Examples 1 and 2 were 140 ppm by mass and 330 ppm by mass, respectively.

### Measurement Conditions

Carrier gas: Helium, 1.0 mL/min
Column: HP-5 MS (manufactured by Agilent Technologies, Inc., trade name)
Oven temperature: After heating at 40° C. for 5 minutes, the temperature was raised to 280° C. at a temperature increase rate of 20° C./min
Mode: SIM (m/z)

### Sensitivity Stability

The above-described photosensitive element was stored at room temperature for three months. The sensitivity of the photosensitive layer in the photosensitive element before storage and after storage was measured by the following method, and an absolute value of a difference in sensitivity before and after storage was calculated. A smaller absolute value indicates a less change in sensitivity and excellent sensitivity stability.

A substrate including an insulation layer and a copper layer was prepared, and the surface of the copper layer was washed with acid, washed with water, and dried. This substrate was heated to 80° C., and then the photosensitive element was laminated such that the photosensitive layer was in contact with the copper layer while peeling off the protective layer of the above-described photosensitive element. Thereby, a laminate including the substrate, the photosensitive layer, and the support in the lamination direction in this order was obtained. The lamination was performed using a heat roll set at 110° C. at a pressure-bonding pressure of 0.4 MPa and at a roll speed of 1.5 m/min.

The above-described laminate was allowed to cool to 23° C. Next, a phototool having a step tablet was attached to the support on the surface of the laminate. As the step tablet, a 41-step tablet with a density range of 0.00 to 2.00, a density step of 0.05, a tablet size of 20 mm×187 mm, and each step size of 3 mm×12 mm was used. Next, the photosensitive layer was exposed through the phototool having a step tablet and the support. The exposure was performed at an exposure dose of 115 mJ/cm² by using a parallel ray exposure apparatus (EXM-1201, manufactured by ORC MANUFACTURING CO., LTD.) having a high-pressure mercury lamp with a wavelength of 365 nm.

After exposure, the support was peeled off from the laminate to expose the photosensitive layer. A 1.0% by mass sodium carbonate aqueous solution set at 30° C. was sprayed to the exposed photosensitive layer for 50 seconds (development treatment) to remove the unexposed area. In this way, a cured film formed of a cured product of the photosensitive resin composition was formed on the copper surface of the laminate. The number of steps of the step tablet of this cured film was visually checked and taken as the sensitivity.

### Color Development Stability

The above-described photosensitive element was stored at room temperature for three months. The hues a*, b*, and DE of the photosensitive layer in the photosensitive element before storage and after storage were measured by the following method, and an absolute value Δa* of a difference in a* before and after storage, an absolute value Δb* of a difference in b* before and after storage, and an absolute value ΔDE of a difference in DE before and after storage were calculated. Smaller absolute values indicate a less change in color development and excellent color development stability.

The above-described photosensitive element was cut into a size of 150 mm×200 mm to obtain a test specimen. After exposing only ½ of the area of the photosensitive layer through the support of the test specimen at room temperature, the test specimen was covered with a light-shielding sheet and left to stand at room temperature for 45 minutes. Next, a, b*, and ΔE of the unexposed area of the photosensitive layer and ΔE of the exposed area were measured through the support using a color difference meter SE7700 (manufactured by NIPPON DENSHOKU INDUSTRIES CO., LTD.). The imaging property DE was calculated by the following formula.

$$DE = Δ Ei - Δ Eu$$

In the formula, ΔEi is ΔE of the exposed area, and ΔEu is ΔE of the unexposed area.

TABLE 1

| | | Example | Comparative | Example | Comparative |
|---|---|---|---|---|---|
| | | 1 | Example 1 | 2 | Example 2 |
| A1 | | 56 | 56 | — | — |
| A2 | | — | — | 56 | 56 |
| FA-321M(70) | | 35 | 35 | 30 | 30 |
| FA-024M | | 4 | 4 | — | — |
| BP-2EM | | 5 | 5 | — | — |
| UA-11 | | — | — | 7 | 7 |
| UA-13 | | — | — | 7 | 7 |
| B-CIM | | 8 | 8 | 4.3 | 4.3 |
| DBA | | 0.65 | 0.65 | — | — |
| EAB | | — | — | 0.03 | 0.03 |
| TBC | | 0.02 | 0.02 | 0.025 | 0.025 |
| LCV | | 0.5 | 0.5 | 0.35 | 0.35 |
| MKG | | 0.02 | 0.02 | 0.01 | 0.01 |
| Cyclopentanone | | 20 | — | 10 | — |
| Toluene | | — | 21 | — | 10 |
| Acetone | | 8 | 8 | 5 | 5 |
| Methanol | | 7 | 7 | 5 | 5 |
| Photosensitive layer | | 25 | 25 | 35 | 35 |
| thickness (μm) | | | | | |
| Sensitivity change | | 0.1 | 1.4 | 0 | 0.4 |
| Color | Δa* | 0.43 | 1.11 | 0.68 | 0.57 |
| development | Δb* | 0.58 | 0.67 | 0.19 | 0.08 |
| change | ΔDE | 0.98 | 1.42 | 0.99 | 3.94 |

### REFERENCE SIGNS LIST

1: photosensitive element, 2, 20: support, 3, 30: photosensitive layer, 4: protective layer, 32: resist pattern, 40: conductor layer, 42: conductor layer after etching treatment, 50: insulation layer, 60: plated layer, 62: plated layer after etching treatment, 70: conductor pattern, 80: active light ray.

1. A photosensitive resin composition comprising: a binder polymer; a photopolymerizable compound; a photopolymerization initiator; a dye; and a solvent, wherein
the solvent contains at least one selected from the group consisting of a ketone-based solvent having an alicyclic skeleton and an aromatic ether-based solvent.

2. The photosensitive resin composition according to claim 1, wherein the ketone-based solvent having an alicyclic skeleton contains at least one selected from the group consisting of cyclopentanone and cyclohexanone.

3. The photosensitive resin composition according to claim 1, wherein the aromatic ether-based solvent contains anisole.

4. The photosensitive resin composition according to claim 1, wherein the solvent does not contain toluene.

5. The photosensitive resin composition according to claim 1, which is film-shaped.

6. A photosensitive element comprising:
a support; and
a photosensitive layer formed using the photosensitive resin composition according to claim 1 on the support.

7. A method for forming a resist pattern, the method comprising:
a step of forming a photosensitive layer using the photosensitive resin composition according to claim 1 on a substrate;
a step of photo-curing a part of the photosensitive layer; and
a step of removing an uncured area of the photosensitive layer.

8. A method for forming a resist pattern, the method comprising:
a step of forming a photosensitive layer using the photosensitive element according to claim 6 on a substrate;
a step of photo-curing a part of the photosensitive layer; and
a step of removing an uncured area of the photosensitive layer.

9. A method for producing a circuit board, the method comprising a step of subjecting a substrate on which a resist pattern is formed by the method for forming a resist pattern according to claim 7 to an etching or plating treatment to form a conductor pattern.

10. A method for producing a circuit board, the method comprising a step of subjecting a substrate on which a resist pattern is formed by the method for forming a resist pattern according to claim 8 to an etching or plating treatment to form a conductor pattern.
